(19) United States
(12) Patent Application Publication
(10) Pub. No.: US 2019/0019995 A1
(43) Pub. Date: Jan. 17, 2019

(54) METHOD OF PATTERNING MULTI-LAYER STRUCTURE

(71) Applicant: Corning Precision Materials Co., LTD., Chungcheongnam-do (KR)

(72) Inventors: Donghyun Kim, Cheon-An Si (KR); Euisoo Kim, Gyeonggi-do (KR); Hyunhee Lee, hungcheongnam-do (KR); JooYoung Lee, Chungcheongnam-do (KR); Gun-sang Yoon, Kyungki-do (KR)

(21) Appl. No.: 16/035,109

(22) Filed: Jul. 13, 2018

(30) Foreign Application Priority Data
Jul. 14, 2017 (KR) 10-2017-0089630

(51) Int. Cl. H01L 51/56; H01L 51/00

(52) U.S. Cl. CPC H01L 51/56; H01L 51/0014; H01L 51/0005

(57) ABSTRACT

A method of patterning a multilayer structure and a method of manufacturing a light extraction substrate of an OLED device. A first layer or a scattering layer having a number of voids therein is formed on a first surface of a substrate. A second layer or a planarization layer is formed on the first layer or the scattering layer such that a surface of a first area of the first layer or the scattering layer is exposed, wherein a portion of a material of the second layer or the planarization layer is infiltrated into the number of voids to be attached to at least a portion of the first surface of the substrate. The first area of the first layer or the scattering layer is removed.

### BACKGROUND

### Field

This application claims the benefit of priority under 35 U.S.C. § 119 of Korean Patent Application Serial No. 10-2017-0089630 filed on Jul. 14, 2017, the content of which is relied upon and incorporated herein by reference in its entirety.

The present disclosure relates to a method of patterning a multilayer structure and, more particularly, to a method of patterning a multilayer structure by forming a second layer on a first layer, such that a portion of an area of the first layer is exposed, and then removing the portion of the area of the first layer.

### Description of Related Art

Multilayer structures formed on substrates are manufactured and used as intermediate products or final products in a variety of technological fields. For example, multilayer structures may be manufactured as intermediate products, for example, in processes of fabricating display devices, semiconductor devices, and lighting devices. The layers of such multilayer structures are required to be patterned to have predetermined sizes as well as accurately positioned shapes.

In this regard, first, forming layers of a multilayer structure having predetermined sizes and accurately positioned shapes from the beginning may be considered. However, this requires the layers of the multilayer structure to be accurately aligned. This may consequently increase process difficulty and require expensive alignment equipment, thereby increasing processing costs.

As a second option, forming layers of a multilayer structure and then removing portions of the layers of the multilayer structure to have predetermined sizes and accurately positioned shapes may be considered. However, this method may also be accompanied by some problems, such as low quality of edges of a finally produced multilayer structure and surface pollution due to residual particles. Therefore, a novel method able to overcome these problems is required.

### SUMMARY

Various aspects of the present disclosure provide an improved method of patterning a multilayer structure to overcome existing problems, such as the low quality of edges of a resultant multilayer structure and surface pollution due to residual particles.

According to an aspect, a method of patterning a multilayer structure may include: forming a first layer from a first layer material on a first surface of a substrate such that a number of voids are formed in the first layer; forming a second layer from a second layer material on the first layer such that a surface of a first area of the first layer is exposed, wherein a portion of the second layer material is infiltrated into the number of voids of the first layer to be attached to at least a portion of the first surface of the substrate; and removing the first area of the first layer.

According to an aspect, a method of manufacturing a light extraction substrate of an organic light-emitting diode device may include: forming a scattering layer from a scattering layer material on a first surface of a substrate such that a number of voids are formed in the light-scattering layer; forming a planarization layer from a planarization layer material on the scattering layer such that a surface of a first area of the scattering layer is exposed, wherein a portion of the planarization layer material is infiltrated into the number of voids of the scattering layer to be attached to at least a portion of the first surface of the substrate; and removing the first area of the scattering layer.

### BRIEF DESCRIPTION OF THE DRAWINGS

FIG. 1 is a flowchart illustrating a method of patterning a multilayer structure according to exemplary embodiments;

FIG. 2 is a cross-sectional view illustrating a method of patterning a multilayer structure according to some of the exemplary embodiments illustrated in FIG. 1;

FIG. 3 is a plan view illustrating a multilayer structure patterned by a method of patterning a multilayer structure according to some of the exemplary embodiments illustrated in FIG. 1;

FIG. 4 is a plan view illustrating a method of patterning a multilayer structure according to some of the exemplary embodiments illustrated in FIG. 1;

FIG. 5 is a cross-sectional view illustrating a method of manufacturing an OLED device according to a Comparative Example;

FIG. 6 is a luminescence image of an OLED device manufactured by the method of manufacturing an OLED device, illustrated in FIG. 5;

FIG. 7 is a cross-sectional view illustrating a method of manufacturing an OLED device according to exemplary embodiments;

FIG. 8 is a luminescence image of an OLED device manufactured by the method of manufacturing an OLED device, illustrated in FIG. 7;

FIG. 9 is an electron microscope image of a first dispersion liquid, used in forming a scattering layer of a light extraction substrate according to exemplary embodiments;

FIG. 10 is an electron microscope image of a second dispersion liquid, used in forming a scattering layer of a light extraction substrate according to exemplary embodiments;

FIG. 11 is an electron microscope image of a cross-section of a light extraction substrate according to exemplary embodiments;

FIGS. 12 to 14 are electron microscope images of a light extraction substrate according to exemplary embodiments, after a first area of a scattering layer has been removed; and

FIG. 15 is an optical microscope image of a light extraction substrate according to exemplary embodiments, after a first area of a scattering layer has been removed.

### DETAILED DESCRIPTION

Hereinafter, embodiments of the present disclosure will be described in detail with reference to the accompanying drawings.

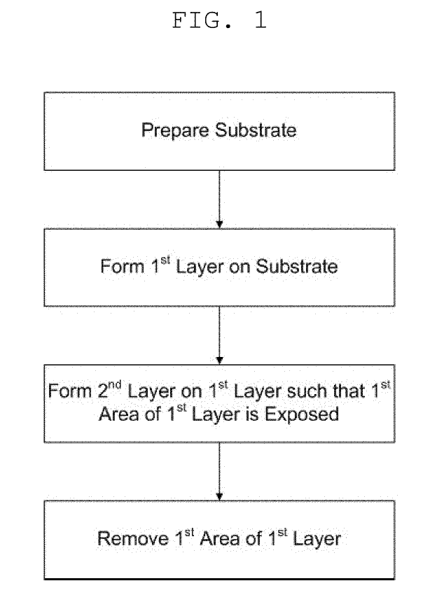

FIG. 1 is a flowchart of a method of patterning a multilayer structure according to exemplary embodiments.

As illustrated in FIG. 1, the method of patterning a multilayer structure may include forming a first layer on a first surface of a substrate, forming a second layer on the first layer such that a surface of a first area of the first layer (i.e. a first surface of the first layer opposite the first surface of the substrate) is exposed, and removing the first area of the first layer.

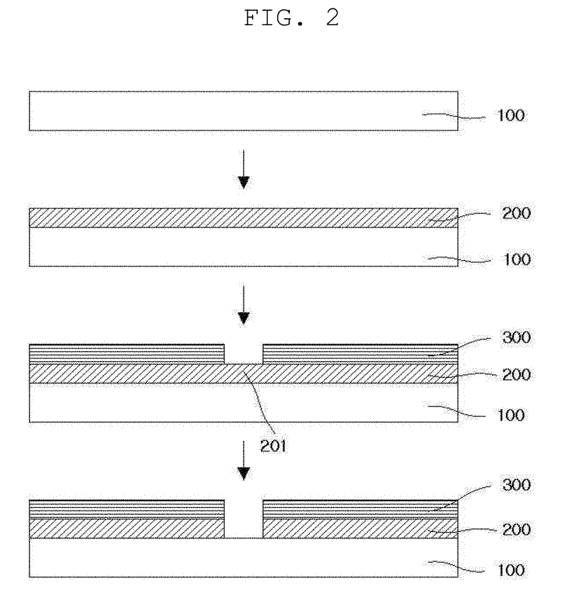

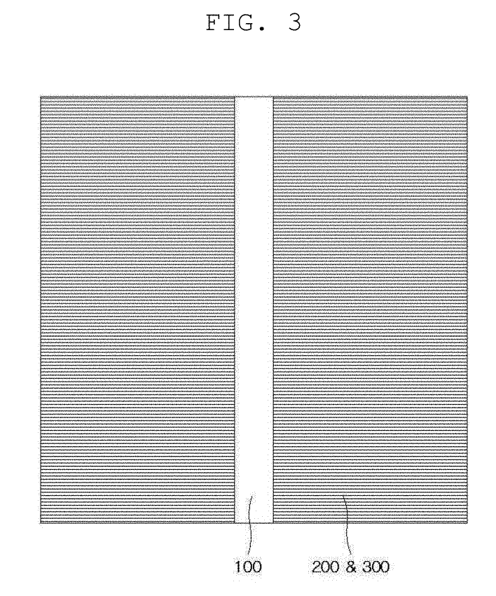

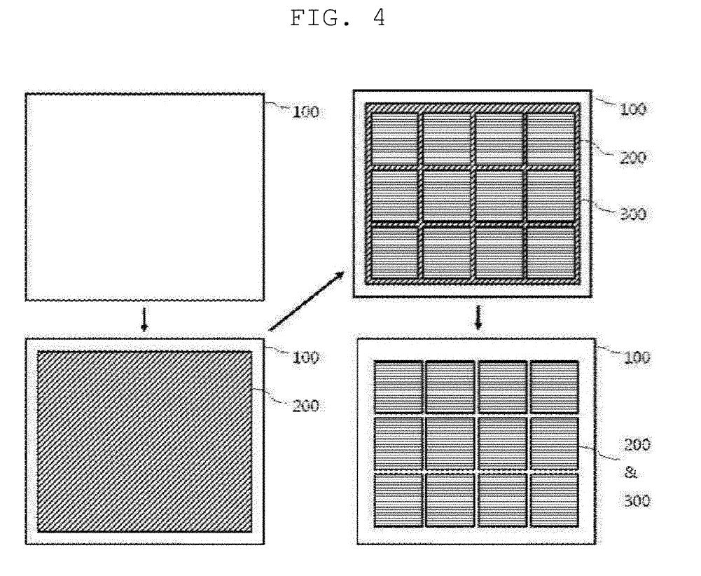

FIG. 2 is a cross-sectional view illustrating a method of patterning a multilayer structure according to some of the exemplary embodiments illustrated in FIG. 1, FIG. 3 is a plan view illustrating a multilayer structure patterned by a method of patterning a multilayer structure according to some of the exemplary embodiments illustrated in FIG. 1, and FIG. 4 is a plan view illustrating a method of patterning a multilayer structure according to some of the exemplary embodiments illustrated in FIG. 1.

A substrate 100 may be one selected from among a glass substrate, a metal oxide substrate, a metal nitride substrate, a synthetic resin substrate, and the like. The glass substrate may be one selected from among a soda-lime glass (SiO₂—CaO—Na₂O) substrate, an aluminosilicate glass (SiO₂—Al₂O₃—Na₂O) substrate, and the like. The substrate 100 may be a glass substrate prepared by a fusion process, a floating process, or the like. The substrate 100 may be formed from chemically strengthened glass or thermally toughened glass. The substrate 100 may be a flexible substrate or a nonflexible substrate. The thickness of the flexible substrate may be 1.5 mm or less.

A first layer material, from which the first layer 200 is formed, may include a metal oxide or the like. The first layer material may be a high refractive index material transmitting visible light. The first layer 200 may be formed by coating the first surface of the substrate 100 with the first layer material. The substrate 100 may be coated with the first layer material by a variety of processes, such as slot die coating, spin coating, and bar-coating. A number of voids may be formed in the first layer 200. The first layer 200 may have a greater porosity than a second layer 300. The sizes (diameters) of the number of voids may range from 10 nm to 700 nm, although the present disclosure is not limited thereto. A volume occupied by the number of voids may range from 20% to 50% of the volume of the first layer 200, although the present disclosure is not limited thereto.

A second layer material, from which the second layer 300 is formed, may be one selected from among an organic material, an inorganic material, and an organic/inorganic hybrimer. The second layer 300 may be formed by coating the first layer with the second layer material. For example, the second layer 300 may be formed by applying the second layer material to the first layer 200 by wet coating. The first layer 200 may be coated with the second layer material by a variety of processes, such as slot die coating, inkjet printing, spin coating, and bar-coating. A portion of the second layer material may be infiltrated into the number of voids of the first layer 200. A portion of the second layer material may be attached to at least a portion of the first surface of the substrate 100 through the first layer. Adhesion of the second layer material to the substrate 100 may be greater than adhesion of the first layer material to the substrate 100. The greater adhesion of the second layer material enables the first layer 200 to be more strongly attached to the substrate 100, such that the remaining area, except for a first area 201 of the first layer 200, may be prevented from being detached when the first area 201 is removed. However, the present disclosure is not limited thereto. For example, the adhesion of the second layer material may be substantially the same as or less than the adhesion of the first layer material. Although the adhesion of the second layer material is less than the adhesion of the first layer material, the first layer 200 can be more strongly attached to the substrate 100 since an adhesive area between the first and second layer material and the substrate 100 is increased. The adhesion of the second layer material may be greater than scale 5B as a result of a cross-cut test described in ASTM D3359.

The first area 201 of the first layer 200 may be removed using a water jet device. Additionally or alternatively, in some embodiments, the first area 201 of the first layer 200 may be removed by brush cleaning. A cleaning solution may be used as a remover to remove the first area 201 of the first layer 200. For example, the first area 201 of the first layer 200 may be removed by applying the cleaning solution to the first area 201 of the first layer 200 using the water jet device. When the first area 201 is removed by the cleaning solution, the first area 201 of the first layer 200 may be clearly removed without particles remaining thereon. Deionized water may be used as the cleaning solution. However, the present disclosure is not limited thereto. Additionally or alternatively, the cleaning water may contain a mechanical abrasive, a chemical mechanical abrasive, or the like. The removal of the first area 201 may be performed by a variety of processes, such as a mechanical process, a chemical process, an optical process, and an electrical process.

Although the removal of the area 201 of the first layer 200 may be completed using a single process only, a plurality of processes may be required to remove the area 201 of the first layer 200. The first area 201 of the first layer 200 is an area extending from the first surface of the first layer 200 to a second surface opposite the first surface. However, an edge surface of the first area 201 of the first layer 200 may not be required to extend exactly in the thickness direction of the first layer 200 (although the first area 201 is illustrated as extending exactly along the vertical direction, i.e. the thickness direction of the first layer 200, in the fourth image of FIG. 2). For example, an area occupied by the first area 201 on the first surface of the first layer 200 may not be required to have exactly the same shape as an area occupied by the first area 201 on the second surface of the first layer 200. For example, when the first area having a stripe shape is intended to be removed, the shape which the first area 201 exhibits on the first surface may be the same as or similar to the stripe shape, while the shape which the first area 201 exhibits on the second surface may be different from the stripe shape. In some of such embodiments, an additional process for making the first area 201 exhibit the stripe shape on the second surface may be performed, but in some alternative embodiments, such an additional process may not be performed.

The first area 201 of the first layer 200 may be positioned at a distance from (i.e. not to adjoin) the entirety or a portion of edges of the first layer 200. For example, the second layer 300 may be formed such that the first area 201 is completely surrounded by the remaining area of the first layer 200, such that the first area 201 of the first layer 200 is spaced apart from (i.e. not to adjoin) the entirety of the edges of the first layer 200. As illustrated in FIG. 3, the first area 201 of the first layer 200 may be spaced apart from (i.e. not to adjoin) portions of the edges of the first layer 200. In addition, as illustrated in FIG. 4, the second layer 300 may be formed such that the first area 201 of the first layer 200 forms (i.e. adjoins) the entirety of the edges of the first layer 200.

The first area 201 of the first layer 200 may include a plurality of segments spaced apart from each other (e.g. a plurality of stripe segments).

As illustrated in FIG. 4, the second layer 300 may be divided into a plurality of segments by the first area 201 of the first layer 200 such that the plurality of segments are spaced apart from each other.

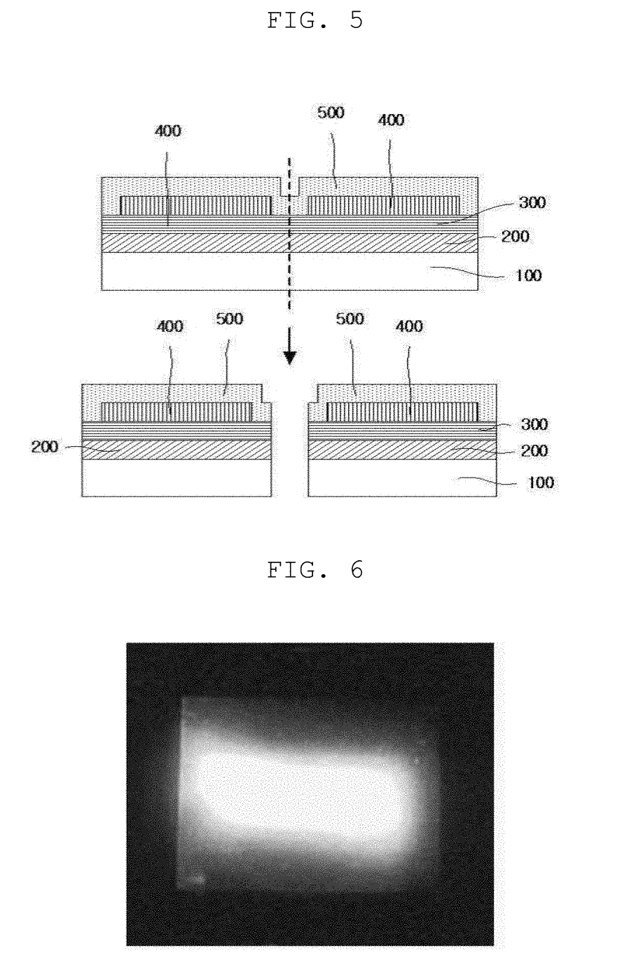

FIG. 5 is a cross-sectional view illustrating a method of manufacturing an organic light-emitting diode (OLED) device according to a Comparative Example, and FIG. 6 is a luminescence image of an OLED device manufactured by the method of manufacturing an OLED device, illustrated in FIG. 5.

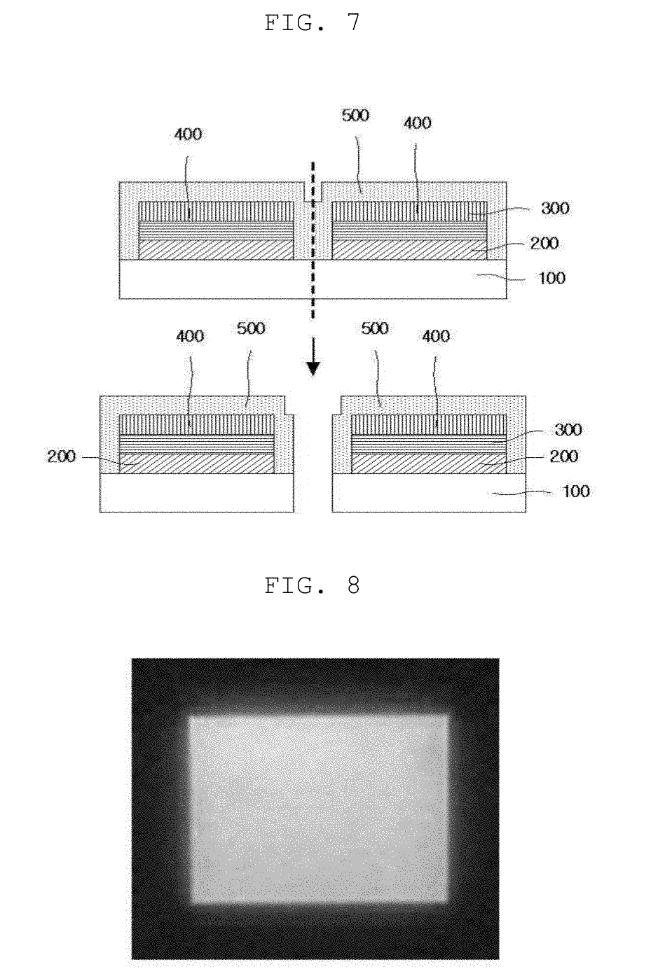

External air or moisture may be infiltrated into the OLED device manufactured by the method of manufacturing an OLED device, illustrated in FIG. 5, through an externally-exposed light extraction layer, thereby causing adverse effects on the light emission characteristics and longevity of an OLED 400. FIG. 6 illustrates a dark streak occurring during luminescence of the OLED device, caused by external air or moisture infiltrated into the OLED device manufactured by the method of manufacturing an OLED device, illustrated in FIG. 5. Therefore, as illustrated in FIG. 7 referred to later, edge exclusion of the light extraction layer is required. FIG. 8 illustrates that an OLED device (having a light-emitting area of about 12×24 mm²) manufactured by the method of manufacturing an OLED device, illustrated in FIG. 7, exhibits reliable light emission characteristics and longevity due to infiltration of external air or moisture being blocked.

FIG. 7 is a cross-sectional view illustrating a method of manufacturing an OLED device according to exemplary embodiments.

A significant portion of light generated by an OLED device may be lost due to total reflection, light waveguiding, surface plasmon, and the like, such that only a small portion of the generated light exits. Research has found that about 80% of the generated light is lost. Therefore, an OLED device can be provided with a light extraction layer to minimize light loss and outwardly extract a maximum amount of light.

The multilayer structure, the first layer 200 and the second layer 300, described with reference to FIGS. 1 to 4, may include a light extraction layer, a scattering layer 200, and a planarization layer 300 for an OLED device, respectively. Descriptions provided with reference to FIGS. 1 to 4 may be equally applied to embodiments described with reference to FIGS. to 15 unless otherwise specified. Likewise, descriptions provided with reference to FIGS. 7 to 15 may be equally applied to embodiments described with reference to FIGS. 1 to 4 unless otherwise specified. The OLED device may be a lighting device in some embodiments, while the OLED device may be a display device in some alternative embodiments. However, the present disclosure is not limited thereto, and the OLED device may be used in a variety of applications.

The method of manufacturing an OLED device includes: forming a scattering layer 200 on a first surface of a substrate 100; forming a planarization layer 300 on the scattering layer 200, such that a surface of a first area of the scattering layer 200 is exposed; and removing the first area of the scattering layer 200.

The scattering layer 200 may be formed by coating. The scattering layer 200 may be formed by wet coating. Prior to formation of the planarization layer 300, the scattering layer 200 may be baked by applying heat thereto. Additionally or alternatively, the scattering layer 200 may be baked together with the planarization layer 300 after the planarization layer 300 is formed. The scattering layer 200 may have voids therein. The voids may have sub-micro size. The sizes (or diameters) of the voids may range from about 10 nm to about 700 nm, although the present disclosure is not limited thereto. The scattering layer 200 may have a higher degree of porosity than the planarization layer 300. The voids of the scattering layer 200 may cause surface roughness on the scattering layer 200.

When an electrode layer of an OLED 400 is directly formed on the scattering layer 200 having the surface roughness, the surface roughness can have a significantly negative effect on the electrical characteristics and longevity of the electrode layer. Therefore, the planarization layer 300 having a lower degree of surface roughness than the scattering layer 200 may be formed on the scattering layer 200. The surface toughness of the scattering layer 200 and the surface roughness of the planarization layer 300 may be compared with each other using various roughness parameters. For example, root-mean-square surface roughness (R_{RMS}) of the planarization layer 300 may be smaller than R_{RMS} of the scattering layer 200. Additionally or alternatively, a roughness average (Ra) of the planarization layer 300 may be smaller than a Ra of the scattering layer 200. The planarization layer 300 may be formed by applying a planarization layer material to the scattering layer 200. A portion of the planarization layer material may be attached to at least a portion of the first surface of the substrate 100 by infiltrating into the voids. The planarization layer 300 may be formed by coating. The planarization layer 300 may be formed by wet coating. The planarization layer 300 may be formed and then may be baked.

The first area of the scattering layer 200 may be removed by a water jet, sonication, or the like. Due to the removal of the first area of the scattering layer 200, a multilayer structure including the scattering layer 200 and the planarization layer 300 may be divided into at least two segments.

The substrate 100 may be diced into a plurality of light extraction substrates, along a first area thereof corresponding to the first area of the scattering layer 200, and then an OLED may be formed on each of the plurality of light extraction substrates. Alternatively, an OLED may be formed on each of the at least two segments before the substrate 100 is diced along the first area thereof corresponding to the first area of the scattering layer 200. As illustrated in FIG. 7, OLEDs 400 are formed on at least two segments, respectively, an encapsulation layer 500 is formed to encapsulate the at least two segments, and then, the substrate 100 is diced along the first area thereof corresponding to the first area of the scattering layer 200. As illustrated in FIG. 7, the single encapsulation layer 500 may encapsulate the entirety of the at least two segments, but the present disclosure is not limited thereto. The encapsulation layer 500 may be comprised of encapsulation layers corresponding to the segments, respectively. The encapsulation layers 500 may be formed such that some encapsulation layers correspond to segments, respectively, and the remaining encapsulation layers commonly capsulate at least two segments.

The OLED 400 includes an anode layer, an organic layer, and a cathode layer sequentially stacked on the planarization layer 300. The organic layer includes a light-emitting layer.

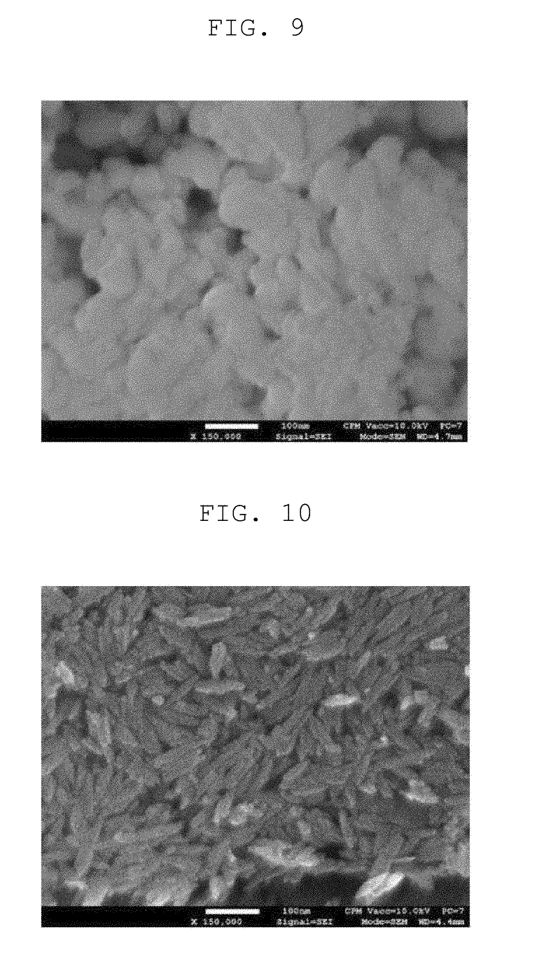

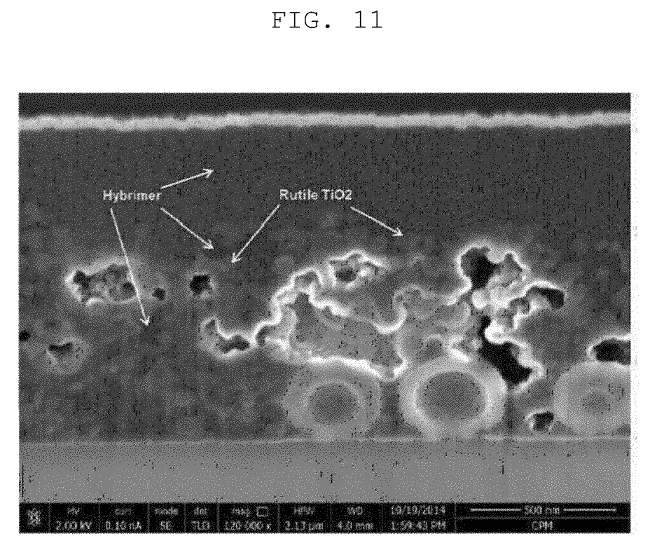

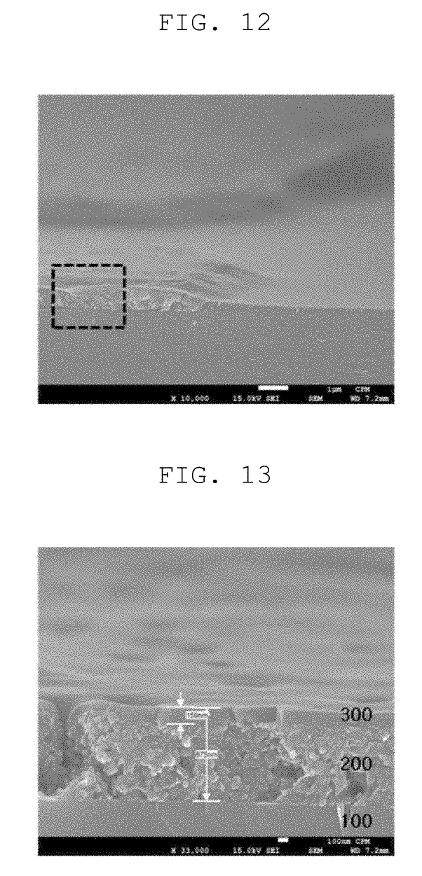

FIG. 9 is an electron microscope image of a first dispersion liquid, used in forming a scattering layer of a light extraction substrate according to exemplary embodiments, FIG. 10 is an electron microscope image of a second dispersion liquid, used in forming a scattering layer of a light extraction substrate according to exemplary embodiments, and FIG. 11 is an electron microscope image of a cross-section of a light extraction substrate according to exemplary embodiments.

A scattering layer material may include first aggregates of metal oxide and second aggregates of metal oxide.

The first aggregates may be aggregates of TiO₂ nanoparticles having sizes ranging from 30 nm to 50 nm. The second aggregates may be aggregates of TiO₂ nanoparticles having sizes ranging 30 nm to 50 nm. The sizes of the first aggregates may range from 0.04 μm to 2.7 μm. The sizes of the second aggregates may range from 0.035 μm to 2.7 μm. The sizes of the first and second aggregates were measured using a particle size analyzer (PSA; Model name: Mastersizer 2000) available from Malvern.

A specific surface area of the first aggregates may be smaller than a specific surface area of the second aggregates. The first aggregates and the second aggregates may have the same chemical composition and the same crystal phase, but may have different crystal habits. The first aggregates and the second aggregates may have a chemical composition of TiO₂. The first aggregates and the second aggregates may have rutile crystalline phase or anatase crystalline phase. The first aggregates may have a dendritic crystal habit, while the second aggregates may have a rod-shaped crystal habit.

Although the first aggregates and the second aggregates have the same chemical composition and the same crystalline phase, the first aggregates and the second aggregates may have different specific surface areas when the first aggregates and the second aggregates have different crystal habits. For example, the first aggregates formed from rutile TiO₂ may have a dendritic crystal habit and a specific surface area of about 30.4 m²/g. In contrast, the second aggregates formed from rutile TiO₂ may have a rod-shaped crystal habit and a specific surface area of about 92.8 m²/g. Therefore, a scattering layer material including the first aggregates and the second aggregates formed from rutile TiO₂ may have a specific surface area greater than 30.4 m²/g and smaller than 92.8 m²/g according to a ratio of the first aggregates and the second aggregates. For example, the specific surface area of the scattering layer material may be about 50 m²/g. The specific surface area may be measured using a gas adsorption analyzer (Macsorb HM Model-1208).

As described above, the first aggregates and the second aggregates may have different shapes, since the first aggregates and the second aggregates follow different aggregating processes. When the first and second aggregates formed from TiO₂, the TiO₂ aggregates of the scattering layer, are formed to have different shapes, a light-scattering effect can be maximized. When the scattering layer is formed, a number of voids having sizes appropriate for scattering light, and having a refractive index of about 1, can be spontaneously formed in the scattering layer in the TiO₂ baking process. Since the TiO₂ aggregates have dendritic shape and rod shape, voids defined between the aggregates can also be formed in various shapes to maximize the light-scattering effect.

The scattering layer may further include a plurality of light-scattering particles. Primary particles of the plurality of light-scattering particles may have sizes ranging from 10 nm to 500 nm. The plurality of light-scattering particles may be arranged in a lower portion of the scattering layer, adjacent to a substrate. The plurality of light-scattering particles form a complex light-scattering structure together with the voids. For example, the plurality of light-scattering particles may be mixed with rutile TiO₂ before being applied to the substrate. Additionally or alternatively, the plurality of light-scattering particles may be formed on the substrate before the scattering layer is formed to thereby cover the plurality of light-scattering particles. The light-scattering particles may be formed from a metal oxide selected from among candidate metal oxides, such as SiO₂, TiO₂, ZrO₂, ZnO, and SnO₂, and combinations thereof.

Since the rutile TiO₂ is a high refractive index (HRI) metal oxide having a refractive index ranging from 2.5 to 2.7, when a plurality of voids having a refractive index of 1 and a plurality of light-scattering particles having a different refractive index are provided, a complexified multi-refractive structure, such as a high-low refractive structure or a high-low-high refractive structure, is formed. The complexified multi-refractive structure has various refractive indices, that is, a maximized refractive index difference. When the complexified multi-refractive structure is disposed on a path along which light generated by an OLED exits, emission paths of the light generated by the OLED can be diversified, thereby maximizing light extraction efficiency of an OLED device.

The thickness of the scattering layer is required to be appropriate, since it is difficult for a planarization layer material to reach the substrate through the scattering layer if the scattering layer is excessively thick. The scattering layer may have a thickness ranging from 0.5 μm to 3.0 μm and the light extraction layer may have a thickness ranging from 1.0 μm to 4.0 μm, although the present disclosure is not limited thereto.

To maximize the light extraction efficiency of the OLED device, the planarization layer may have a refractive index different from that of the scattering layer. The planarization layer may be formed from an organic material, an inorganic material, or an organic/inorganic hybrimer. Polydimethylsiloxane (PDMS) having a refractive index of 1.3 to 1.5 may be used as the organic material, from which the planarization layer is formed. The planarization layer may be formed from a material selected from among inorganic materials having a refractive index ranging from 1.7 to 2.7, including metal oxides, such as MgO, Al₂O₃, ZrO₂, SnO₂, ZnO, SiO₂, and TiO₂, and high refractive polymers. Since the scattering layer is formed from a high refractive index material of TiO₂, the planarization layer material may be selected among materials the refractive indices of which are lower than the refractive index of TiO₂. When the light extraction layer having a multilayer structure comprised of different refractive layers is disposed on the path along which light generated by the OLED exits, as described above, the light extraction efficiency of the OLED device can be improved due to the refractive index difference.

Only a portion of a total volume occupied by the number of voids of the scattering layer may be filled with the planarization layer material. In some embodiments, the number of voids of the scattering layer may be uniformly distributed, such that the scattering layer may function as having a single refractive index between the refractive index of a base material thereof and the refractive index of the voids. Thus, the scattering layer itself may not have a significant light-scattering effect. In this regard, in some embodiments, the number of voids of the scattering layer may be non-uniformly filled with the planarization layer material to maximize a light-scattering effect.

The scattering layer be formed by preparing a first dispersion liquid by dispersing first aggregates in a first solvent; preparing a second dispersion liquid by dispersing second aggregates, the specific surface area of which differs from the specific surface area of the first aggregate, in a second solvent; preparing a mixture dispersion liquid by mixing the first dispersion liquid and the second dispersion liquid; and coating the first surface of the substrate with the mixture dispersion liquid. For example, the first dispersion liquid is prepared by dispersing first aggregates formed from rutile or anatase TiO₂, in particular, TiO₂ aggregates having a dendritic crystal habit, in the first solvent. In the preparation of the first dispersion liquid, TiO₂ may be dispersed in the first solvent in an amount of 5 wt % to 60 wt %. The first solvent may include an organic solvent or H₂O. The second dispersion liquid may be prepared by dispersing second aggregates formed from rutile TiO₂ in the second solvent. In particular, the second aggregates may be TiO₂ aggregates having a rod-shaped crystal habit, the specific surface area of which is greater than the specific surface area of the first aggregates. In the preparation of the second dispersion liquid, TiO₂ may be dispersed in the second solvent in an amount of 5 wt % to 60 wt %. The second solvent may include an organic solvent, such as EtOH. Afterwards, the mixture dispersion liquid to be applied to the substrate is prepared by mixing the first dispersion liquid and the second dispersion liquid. In some embodiments, a plurality of light-scattering particles may be mixed with the mixture dispersion liquid.

In subsequence, the scattering layer is formed by coating the substrate with the mixture dispersion liquid. In the scattering layer formed in the manner as described above, a plurality of voids may be spontaneously formed in the scattering layer, and the plurality of light-scattering particles, mixed with the mixture dispersion liquid during in the preparation of the mixture dispersion liquid, may be arranged in a lower portion of the scattering layer.

Afterwards, the planarization layer is formed on the scattering layer.

### Examples

FIGS. 12 to 14 are electron microscope images of a light extraction substrate according to exemplary embodiments, after a first area of a scattering layer has been removed.

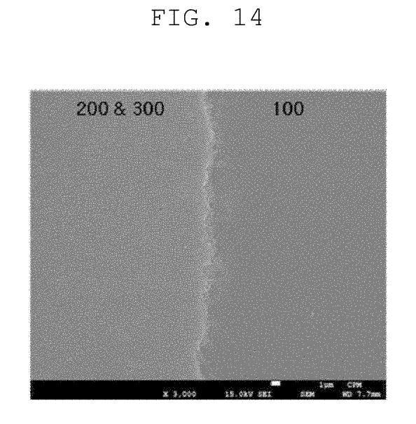

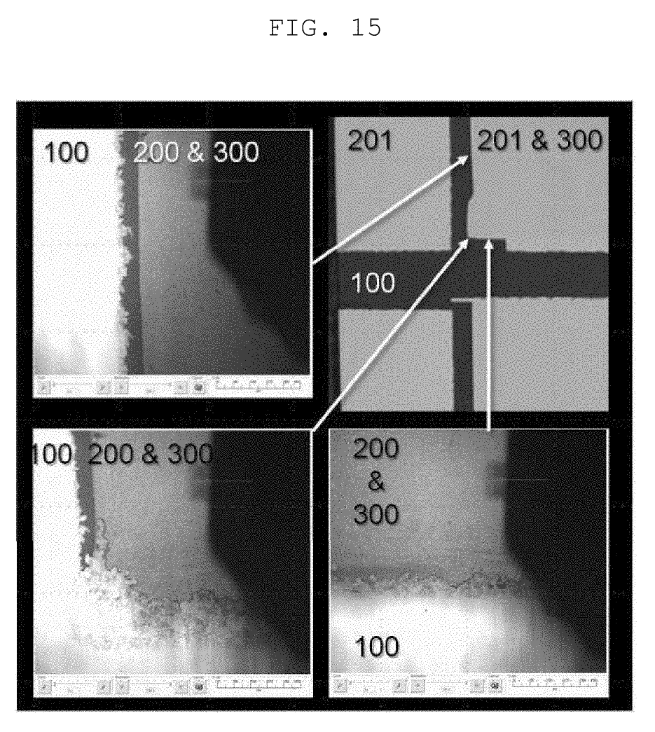

A porous TiO₂ scattering layer was formed and then a planarization layer was formed on the scattering layer by coating the scattering layer with an organic/inorganic hybrimer available from Toray Industries by bar-coating. Afterwards, only a first area of the scattering layer, not coated with the planarization layer, was selectively wiped using a wiper available from Ultima company, wetted with ethanol. In subsequence, images were captured using an electron microscope. FIG. 12 is an image of the light extraction substrate captured in an inclined direction such that both a cross-section along the thickness and a top surface of the light extraction substrate are simultaneously captured, FIG. 13 is an enlarged image of the oblong box in FIG. 12, and FIG. 14 is an image of a top surface of the light extraction substrate. In FIGS. 12 and 14, left portions illustrate the substrate, as well as the scattering layer and the planarization layer stacked on the substrate, and right portions illustrate only the substrate from which the scattering layer and the planarization layer are removed. According to the experiment, it can be appreciated that the first area of the first layer (i.e. the scattering layer), not coated with the second layer (i.e. the planarization layer), can be relatively easily removed without damaging the coating state of the second layer.

FIG. 15 is an optical microscope image of a light extraction substrate according to exemplary embodiments, after a first area of a scattering layer has been removed.

A porous scattering layer formed from TiO₂ was formed, and a planarization layer was formed on the scattering layer by coating the scattering layer with an organic/inorganic hybrimer available from Toray Industries. Afterwards, only a first area of the scattering layer, not coated with the planarization layer, was selectively removed using a water jet at a level of pressure of 200 bars. Subsequently, images were captured using an optical microscope. The images were captured at a magnification of 10 times. Among four quadrants of FIG. 15, an upper-right quadrant illustrates images of a top surface of the light extraction substrate, while remaining three quadrants illustrate images obtained by capturing the top surface of the light extraction substrate using an optical microscope. The enlarged images of the upper-right quadrant are illustrated in the remaining three quadrants. According to the experiment, it can be appreciated that the first area of the scattering layer, not coated with the planarization layer, is relatively easily removed without damaging the coating state of the second layer.

What is claimed is:

1. A method of patterning a multilayer structure comprising:
forming a first layer from a first layer material on a first surface of a substrate such that a number of voids are formed in the first layer;
forming a second layer from a second layer material on the first layer such that a surface of a first area of the first layer is exposed, wherein a portion of the second layer material is infiltrated into the number of voids of the first layer to be attached to at least a portion of the first surface of the substrate; and
removing the first area of the first layer.

2. The method of claim 1, wherein adhesion of the second layer material to the substrate is stronger than adhesion of the first layer material to the substrate.

3. The method of claim 1, wherein porosity of the first layer is greater than porosity of the second layer.

4. The method of claim 1, wherein forming the second layer comprises applying the second layer material to the first layer by wet coating.

5. The method of claim 1, wherein forming the second layer comprises applying the second layer material to the first layer by inkjet printing.

6. The method of claim 1, wherein removing the first area comprises cleaning the first area of the first layer using a cleaning solution.

7. The method of claim 6, wherein the cleaning solution comprises deionized water.

8. The method of claim 6, wherein removing the first area comprises applying the cleaning solution to the first area of the first layer using a water jet device.

9. A method of manufacturing a light extraction substrate of an organic light-emitting diode device, the method comprising:
forming a scattering layer from a scattering layer material on a first surface of a substrate such that a number of voids are formed in the light-scattering layer;
forming a planarization layer from a planarization layer material on the scattering layer such that a surface of a first area of the scattering layer is exposed, wherein a portion of the planarization layer material is infiltrated into the number of voids of the scattering layer to be attached to at least a portion of the first surface of the substrate; and
removing the first area of the scattering layer.

10. The method of claim 9, wherein adhesion of the planarization layer material to the substrate is stronger than adhesion of the scattering layer material to the substrate.

11. The method of claim 9, wherein porosity of the scattering layer is greater than porosity of the planarization layer.

12. The method of claim 9, wherein sizes of the number of voids range from 10 nm to 70 nm.

13. The method of claim 9, wherein the number of voids occupy 20% to 50% of a volume of the scattering layer.

14. The method of claim 9, wherein forming the planarization layer comprises applying the planarization layer material to the scattering layer by wet coating.

15. The method of claim 9, wherein the scattering layer material comprises first aggregates formed from a metal oxide and second aggregates formed from a metal oxide, a specific surface area of the first aggregates being smaller than a specific surface area of the second aggregates.

16. The method of claim 9, wherein the scattering layer material comprises first aggregates formed from a metal oxide and second aggregates formed from a metal oxide, the first aggregates having a same chemical composition and crystal phase as and a different crystal habit from the second aggregates.

17. The method of claim 16, wherein the same chemical composition comprises TiO₂, the same crystal phase comprises a rutile crystalline phase or an anatase crystalline phase, the first aggregates have a dendritic crystal habit, and the second aggregates have a rod-shaped crystal habit.

18. The method of claim 9, wherein forming the scattering layer comprises:
preparing a first dispersion liquid by dispersing first aggregates in a first solvent and preparing a second dispersion liquid by dispersing second aggregates in a second solvent;
mixing the first dispersion liquid and the second dispersion liquid to prepare a mixture of the first dispersion liquid and the second dispersion liquid and coating the first surface of the substrate with the mixture of the first dispersion liquid and the second dispersion liquid,
wherein the first solvent comprises H₂O and an organic solvent, and the second solvent comprises an organic solvent.

19. The method of claim 9, wherein only a portion of a total volume occupied by the number of voids is filled with the planarization layer material.

20. The method of claim 9, wherein the planarization layer material comprises an organic/inorganic hybrimer.

21. A method of manufacturing an organic light-emitting diode device, the method comprising:
forming a scattering layer from a scattering layer material on a first surface of a substrate such that a number of voids are formed in the light-scattering layer;
forming a planarization layer from a planarization layer material on the scattering layer such that a surface of a first area of the scattering layer is exposed, wherein a portion of the planarization layer material is infiltrated into the number of voids of the scattering layer to be attached to at least a portion of the first surface of the substrate; and
removing the first area of the scattering layer.

22. The method of claim 21, further comprising dicing a first area of the substrate corresponding to the first area of the scattering layer.

23. The method of claim 21, wherein removing the first area of the scattering layer results in dividing a multilayer structure including the scattering layer and the planarization layer into at least two segments,
the method further comprising:
forming organic light-emitting diodes on the at least two segments, respectively;
forming an encapsulation layer encapsulating the organic light-emitting diodes and the at least two segments; and
dicing a first area of the substrate corresponding to the first area of the scattering layer.
